(19) United States
(12) Patent Application Publication
(10) Pub. No.: US 2008/0121709 A1
(43) Pub. Date: May 29, 2008

(54) Semiconductor Chip With Identification Codes, Manufacturing Method Of The Chip And Semiconductor Chip Management System

(75) Inventors: Hiroaki Hayashi, Tokyo (JP); Ryoichi Inanami, Kanagawa (JP); Katsumi Kishimoto, Kyoto (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Minato-ku (JP)

(21) Appl. No.: 11/721,626

(22) PCT Filed: Dec. 12, 2005
(86) PCT No.: PCT/JP05/23185

§ 371 Date: Jun. 13, 2007

(30) Foreign Application Priority Data
Dec. 13, 2004 (JP) 2004-360181

(51) Int. Cl. G06K 7/14; H01L 21/768; G06K 19/06

(52) U.S. Cl. 235/454; 235/492; 438/598; 257/E21.575

(57) ABSTRACT

There is provided a semiconductor chip using an electrical identification code and an optical identification code, both of the codes being formed in the same process to be always in one-to-one correspondence with each other. An optically readable wiring pattern associated with an electrically readable identification code is formed on a top layer of the semiconductor chip or a layer that is optically identifiable from the top layer, and used as an optical identification code. The semiconductor chip is thus provided such that the optically readable wiring pattern is part of wiring of memory elements that electrically store an identification code, and comprised of a combination of wiring forms set as 1 or 0 that is an output of each of the memory elements.

### TECHNICAL FIELD

The present invention relates to means for identifying a semiconductor chip by identification code, and more particularly, to a semiconductor chip that is identified using both an optically readable identification code and an electrically readable identification code, method of manufacturing such a chip, and semiconductor chip management system using such identification codes.

### BACKGROUND ART

A semiconductor device is tested for the presence or absence of a defect at the stage of chip or wafer or when an integrated circuit is formed, and information of a result of the test is indicated on each chip as an identification code. As a code of the test information, an optically readable identification code such as a bar code and marking is often used because the information amount is relatively small.

Meanwhile, for process control, follow-up survey of quality and the like, as well as the test information as described above, it becomes necessary to indicate manufacturing history of a wafer, chip position information on a wafer, manufacturing history of an integrated circuit formed on a chip and the like on the chip as an identification code. Since such a multipurpose identification code has a large amount of information, it is difficult to use an optical identification code such as a bar code, and there are many cases of using an electrical identification code using semiconductor memory.

Generally, for the electrical identification code, a plurality of memory elements (e.g. ROM) dedicated to the identification code is provided at a predetermined portion (portion with no integrated circuit formed in the chip) around a semiconductor chip, and a combination of binary information of the elements constitutes the code. As a method of reading information from the electrical identification code, there is a method of linking the output line to an output line of a probe test of the IC chip body, and reading the information from an output of the probe, but generally performed is a method of wire bonding the IC chip on a package and reading the electrical identification code. Accordingly, it is only after the IC chip is packaged that use of the information of the identification code becomes possible, and there arises such a problem that this method is not sufficient as a management system of manufacturing control.

Further, in recent years, SiP (System in Package) has been used frequently where a plurality of IC chips is contained in one package. In such a system, it is particularly necessary to strictly perform process control to select IC chips, and required is means for identifying a type of IC chip and the presence or absence of a defect before the chip is packaged. For such a purpose, an optical identification code is suitable which enables readout of the code without the need of wiring. Therefore, in recent years, some systems have been proposed for managing semiconductor chips using both the electrical identification code and optical identification code (for example, JP 2001-525993 and JP 2002-184872).

### DISCLOSURE OF INVENTION

In both JP 2001-525993 and JP 2002-184872 as described above, a bar code or similar code is used as an identification code by optical means. However, a bar code that can be formed on a chip of several millimeters square must be of miniature size, and limits an amount of information to handle, and considerable effort seems to be required for the process to form a micro code.

When an electrical identification code and optical identification code are both used, an integrated circuit as a main body and an electrical identification code dedicated circuit are first formed, and the optical identification code is formed on the surface. Such a method increases the number of manufacturing steps of the chip, and is not preferable. Accordingly, means is desired for integrally forming the electrical identification code and optical identification code in the same process step.

Generally, techniques of lithography used in forming an integrated circuit are considered to be means for forming an extremely fine optically identifiable pattern with accuracy and reliability. Accordingly, using the techniques has a possibility of integrally forming the electrical identification code and optical identification code in the same process step.

Meanwhile, in using both the electrical identification code and optical identification code, when the codes have information in no correlation with each other, the information needs to be stored in computer memory in correspondence with each other. One of purposes of the identification code is to enable follow-up survey in response to changes in quality of a semiconductor chip with time. For this purpose, it is necessary to store the identification code information of an enormous amount of semiconductor chips for many years. Accordingly, the codes in no correlation are not preferable, and it is desired that both codes always have one-to-one correspondence.

Therefore, in the present invention, in a semiconductor chip using both an electrical identification code and optical identification code or a management system of the chip, it is an object to provide means for forming an optical identification code in the same step as a step of forming an electrical identification code using the technique of forming a semiconductor pattern, while providing the codes that are always in one-to-one correspondence with each other.

A semiconductor chip of the invention to achieve the aforementioned object is a semiconductor chip using an optically readable wiring pattern associated with an electrically readable identification code as an optical identification code.

In the semiconductor chip, it is preferable that the optically readable wiring pattern is formed on a top layer of the semiconductor chip or a layer that is optically identifiable from the top layer.

Further, in the semiconductor chip, it is preferable that the wiring pattern is part of wiring of memory elements that electrically store an identification code, and is a combination of wiring forms set as 1 or 0 that is a binary output value of each of the memory elements.

In a method of manufacturing a semiconductor chip of the invention, a plurality of memory elements to store an electrical identification code is formed on a wafer, a wiring layer is formed on the memory elements via an insulating layer, the wiring layer is coated with a resist film, a wiring pattern is formed such that an output value of each of the memory elements is 1 or 0 by electron beam lithography or laser beam lithography, the wiring layer is etched with the wiring pattern, and an optically readable wiring pattern associated with the electrical identification code is thereby formed.

In the manufacturing method, it is preferable that the wiring pattern is formed on a layer optically identifiable from a top layer.

Further, a system of managing a semiconductor chip of the invention is to manage a semiconductor chip using an optically reading apparatus that reads an optically readable wiring pattern of a memory element associated with an electrically readable identification code, an electrically reading apparatus that reads the electrically readable identification code, and output information of the optically reading apparatus and of the electrically reading apparatus.

In the management system, the optically readable wiring pattern is preferably formed on a top layer of a semiconductor chip or a layer optically identifiable from the top layer, and more preferably, is part of wiring of memory elements to electrically store an identification code, while being a combination of wiring forms such that a binary output value of each of the memory elements is 1 or 0.

In the semiconductor chip of the invention, the identification code to electrically read and the identification code to optically read are completely equivalent to each other, and it is possible to use the codes in such a manner that identification is made mainly optically before the semiconductor chip is incorporated into a package, and is made mainly electrically after incorporating the chip. Further, it is ensured that both the codes are always equivalent to each other, and the need is eliminated of storing the correspondence between both the codes to store.

Further, in the present invention, it is possible to form the electrical identification code and optical identification code in the same process step using the conventional semiconductor manufacturing method, and to simplify the manufacturing process as compared with the case of forming both codes separately.

### BRIEF DESCRIPTION OF DRAWINGS

The above and other objects and features of the invention will appear more fully hereinafter from a consideration of the following description taken in connection with the accompanying drawing wherein one example is illustrated by way of example, in which;

FIGS. 1A to 1C are exploratory views of a semiconductor chip with identification codes of the invention;

FIGS. 2A to 2C are views illustrating a configuration of a memory element used in an embodiment of the invention;

FIGS. 3A and 3B are exploratory views of a method of using a wiring pattern as an optical identification code in this embodiment;

FIG. 4 is an exploratory view of correspondence between the optical identification code and an electrical identification code in this embodiment;

FIGS. 5A to 5C are views showing an example of a method of manufacturing the semiconductor chip of the invention;

FIGS. 6A to 6D are views showing another example of the method of manufacturing the semiconductor chip of the invention;

FIGS. 7A and 7B are views showing another example of a placement of the identification codes in the semiconductor chip of the invention; and

FIGS. 8A and 8B are views showing an embodiment of logic circuits to read out the electrical identification code stored in the semiconductor chip.

### BEST MODE FOR CARRYING OUT THE INVENTION

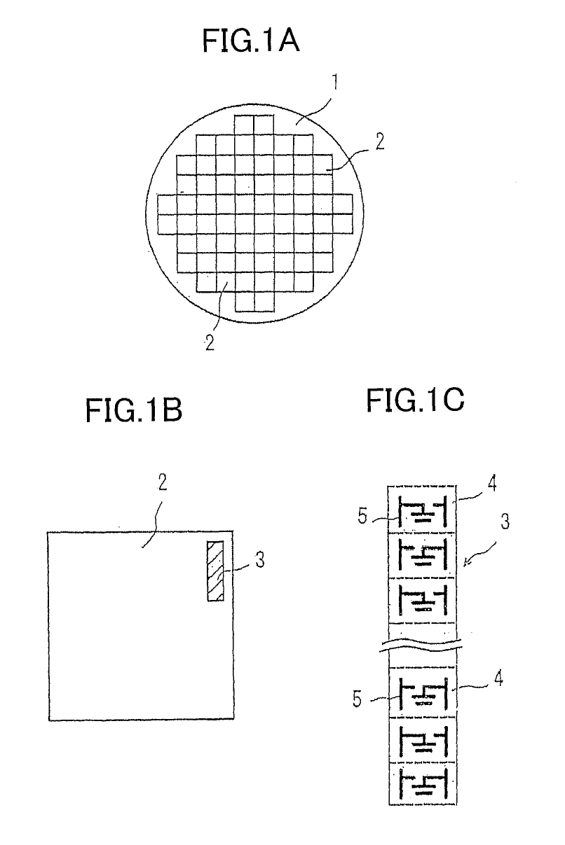

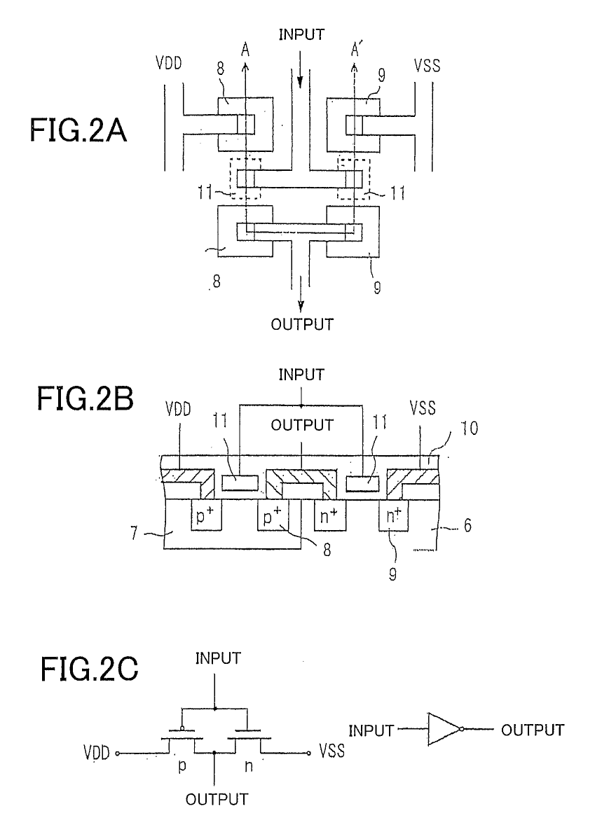

Preferred embodiments of the invention will specifically be described below with reference to accompanying drawings. FIGS. 1A to 1C are exploratory views of a semiconductor chip with identification codes of the invention, where an identification code 3 is formed at a predetermined position near the outer edge of each chip 2 divided from a wafer 1. The identification code 3 features an integrated form of an electrically stored code and optically readable code. In other words, as shown in FIG. 1C, an electrical identification code is formed of a combination of a plurality of memory elements 4 (shown by dashed lines in the figure), and as the memory element 4, an inverter as shown in FIGS. 2A to 2C is used, for example. Wiring patterns 5 of the memory elements 4 are configured to be optically readable from outside, and are used as an optical identification code. The optical identification code is to read the wiring patterns 5 as binary information of 0 or 1, and binary output values of the memory elements 4 forming the electrical identification code are configured to be in one-to-one correspondence with binary output values of the optical identification code.

FIGS. 2A to 2C are views illustrating a configuration of the memory element used in an embodiment of the invention, where FIG. 2A is a schematic plan view, FIG. 2B is a schematic view of section (in substantially U-shape) taken along line A-A′ of FIG. 2A, and FIG. 2C illustrates equivalent circuits.

A C-MOS transistor used as the memory element in this embodiment is formed of coupled p-MOS and n-MOS transistors as shown in FIG. 2C. As shown in FIG. 2B, an n-area 7 is formed in a p-area of a silicon board 6. A pair of p-wells 8 are formed in the n-area 7 to be the source and drain of the p-MOS. Similarly, a pair of n-wells 9 are formed in the p-area of the original board to be the source and drain of the n-MOS.

Gates 11 of polysilicon are formed between the p-wells 8 and between the n-wells 9 via an insulating film 10, and a same input is supplied to both the gates. By aluminum wiring, the source side of the p-well is connected to VDD, the drain side of the n-well is connected to VSS, and the drain of the p-well is connected to the source of the n-well to fetch an output. The C-MOS transistor is an inverter, and the output is low when the input is high, while the output is high when the input is low.

In addition, the memory element used in the invention is not limited to the aforementioned example, and may be simply an n-MOS or p-MOS transistor. Further, in the case of C-MOS, the wiring scheme is not limited to the aforementioned example.

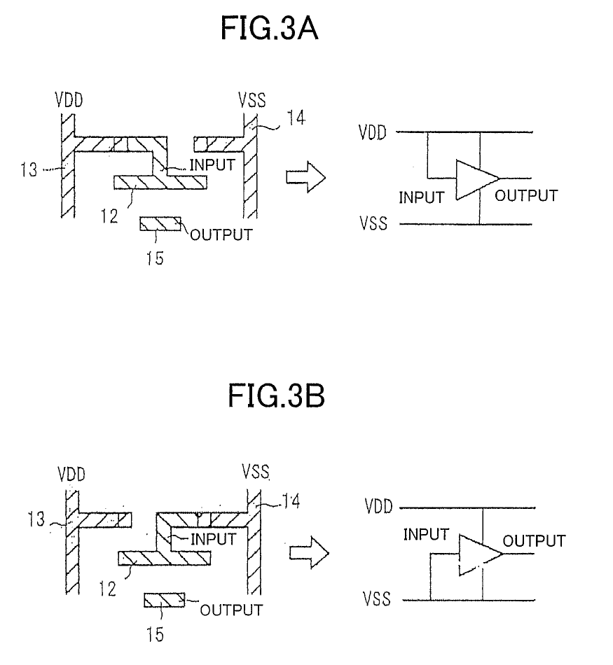

FIGS. 3A and 3B are exploratory views of a method of using a wiring pattern as an optical identification code in this embodiment. As can be seen from the figure, by connecting an input line 12 coupled to both gates of the p-MOS and n-MOS to either of the VDD line 13 side (FIG. 3A) or VSS line side 14 (FIG. 3B), it is possible to obtain a binary output of high or low as an electrical identification code, and to concurrently identify the wiring pattern optically to be binary information. In addition, a buffer cell is used as the logic circuit as shown in FIGS. 3A and 3B, but the present invention is not limited to such a case, and the logic circuit may be an inverter.

The wiring pattern can be formed on either a top layer of a semiconductor chip or a layer that is optically identifiable from the top layer. Further, using at least optically expanding means or image processing means is enough to enable a lacking portion of the wiring of FIGS. 3A and 3B to be distinguished with reliability. Accordingly, by using the lacking portion as an optical identification code, it is possible to obtain a binary output of the optical identification code corresponding to an output of 1 or 0 of the electrical identification code. In addition, an output line 15 always exists at the same position, and is not related to the binary information.

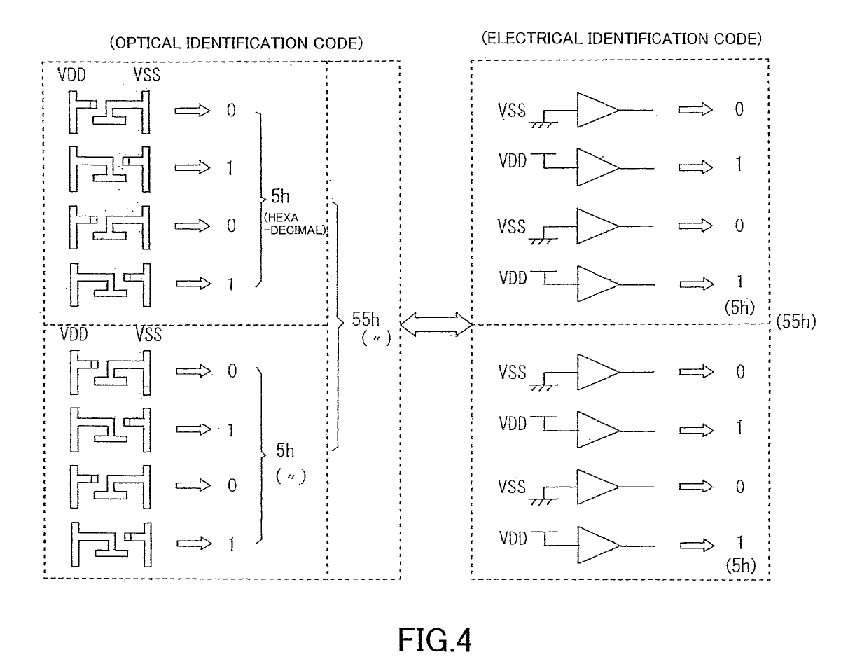

FIG. 4 is an exploratory view of correspondence between the optical identification code and electrical identification code in this embodiment. In this example, information of four memory elements is set as a group to indicate in hexadecimal. In other words, an element connected to the VSS line 14 side is set as 0 both optically and electrically, while an element connected to the VDD line 13 side is set as 1. The optical identification code and electrical identification code are thereby completely equivalent to each other.

In this example, the code of four upper or lower memory elements is (0101) and “5h” in hexadecimal notation, and the code of upper and lower elements is (01010101) and “55h” in hexadecimal notation. This is only one example, and in the semiconductor chip of the invention, since the optical identification code and electrical identification code are brought into complete one-to-one correspondence (equivalent) with each other, it is not necessary to associate both codes with each other to store in memory. Further, such a problem does not occur that the codes become in disagreement with each other by some error, and thereby, cannot be determined.

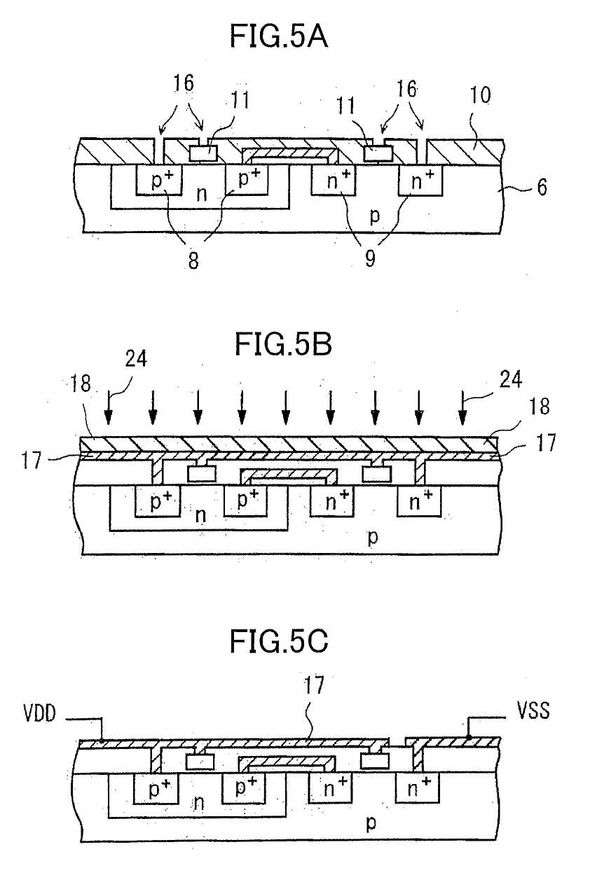

A method of manufacturing the semiconductor chip of the invention will be described below. FIGS. 5A to 5C are exploratory views showing an example of the manufacturing process of the semiconductor chip in this embodiment. First, as shown in FIG. 5A, doping elements are added to the silicon board 6 in ion implantation, the p-wells 8 and n-wells 9 are formed, and the gates 11 of polysilicon are formed on an insulating film by CVD or the like. Further, the thick insulating film 10 is formed thereon, and contact holes 16 are formed by patterning with a resist mask to connect each element to metal wiring.

Next, as shown in FIG. 5B, the entire element surface is coated with an aluminum film 17 by vacuum deposition, a resist film 18 for electron beam is formed on the film 17, a pattern corresponding to an identification code assigned for each chip is formed on the resist film 18 by direct lithography with electron beam 24, and unnecessary portions are etched and removed. A predetermined wiring pattern as shown in FIG. 5C is thus obtained.

To protect the wiring pattern, a transparent protection film may be formed on the surface of the pattern when necessary. In addition, the case of using the electron beam in lithography for the wiring portions is described above, and using the laser beam also results in the same process as in the case described above.

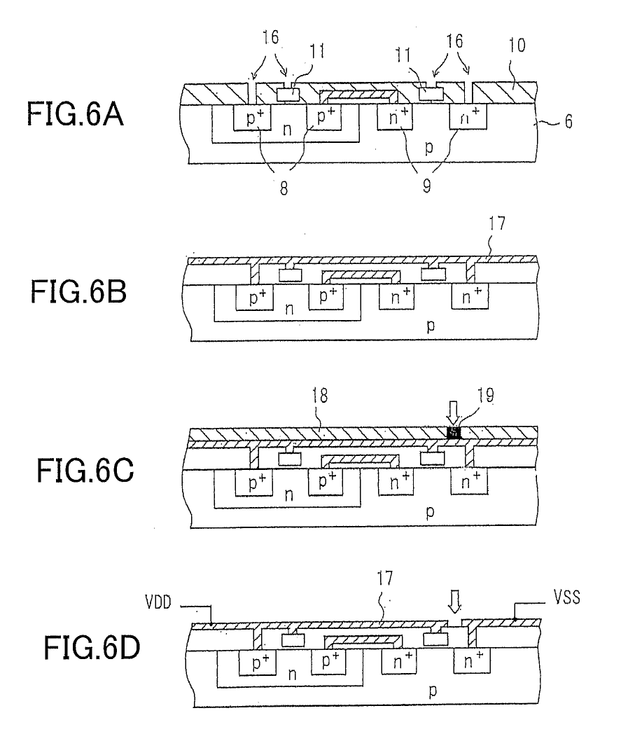

FIGS. 6A to 6D are exploratory views showing another example of the manufacturing process of the semiconductor chip. In this example, as shown in FIG. 6A, the p-wells 8, n-wells 9, insulating film 10, and contact holes 16 are formed on the silicon board 6 in the same way as in the foregoing. As shown in FIG. 6B, the entire element surface is coated with the aluminum film 17 by vacuum deposit, and unnecessary portions are etched and removed using the photoresist as a mask to form a predetermined wiring pattern. In this stage, the wiring pattern (obtained by superimposing patterns of FIGS. 3A and 3B) is formed such that the gate electrode 11 is connected to both the VDD line and VSS line.

Next, as shown in FIG. 6C, the resist film 18 for electron beam is formed, and a cutting portion 19 of the aluminum wiring is rendered by electron beam lithography. The aluminum wiring of the portion rendered by the electron beam is cut by etching, and the resist film 18 is removed, thereby obtaining the predetermined wiring pattern (the pattern of FIG. 3A or 3B) as shown in FIG. 6D.

Among aforementioned process steps, steps up to FIG. 6B, i.e. formation of the source, drain and gate, formation of the inter-layer insulating film and contact hole, and formation of the aluminum wiring with a predetermined pattern, are the same as in a method used in manufacturing an integrated circuit that is a main body, and generally, can be produced concurrently with the circuit. Accordingly, steps specific to the identification code are only of forming the resist film for electron beam, rendering the cut portion by electron beam lithography, and removing the wiring of the rendered portion by etching, and the process of forming the identification code is thus reduced.

When an extremely fine pattern is used as an optical identification code, it is necessary to apply the semiconductor lithography technique to form the pattern, and significant increases in process step are generally indispensable, but according to the method of the invention, it is possible to largely reduce process steps.

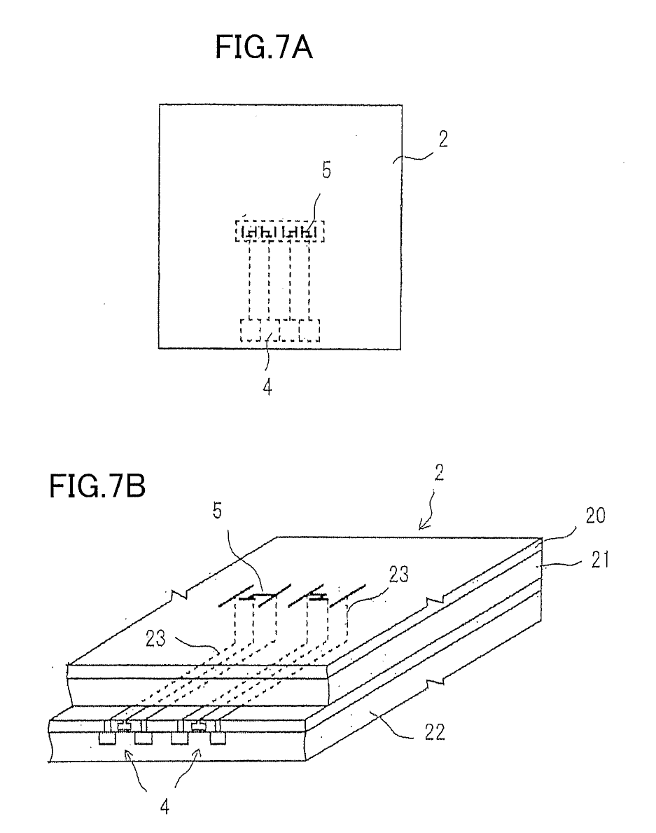

FIGS. 7A and 7B are views showing another example of a placement of the identification codes in the semiconductor chip of the invention, where FIG. 7A is a schematic plan view, and FIG. 7B is a perspective view schematically showing part of a section. In this example, the wiring pattern 5 forming the optical identification code and the memory elements 4 forming the electric identification code are not disposed in the same upper and lower positions. As shown in FIG. 7A, the memory elements 4 are disposed on the periphery of the semiconductor chip 2, the wiring pattern 5 is disposed near the center, and the elements and pattern are connected by wiring.

Further, as shown in FIG. 7B, the wiring pattern 5 is formed on the surface of a top layer 20 of the semiconductor chip 2, the memory elements 4 are formed in a bottom layer 22, and the pattern 5 and elements 4 are coupled by long wiring 23. By thus configuring, an intermediate layer 21 can be used freely for any purposes (for example, integrated circuit body and wiring of the circuit body). Furthermore, an upper surface of the top layer (protection layer or insulating layer) generally does not have other wiring and the like, is used freely, and does not have any trouble to provide the wiring pattern 5 and wiring 23.

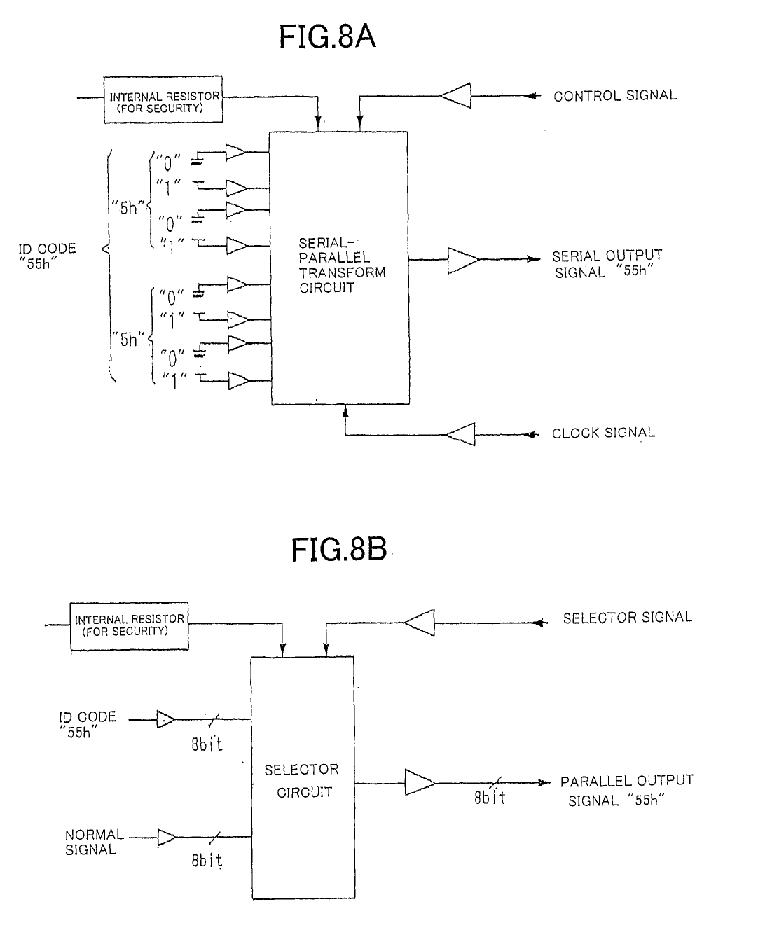

FIGS. 8A and 8B show an embodiment of logic circuits to read out the electrical identification code stored in the semiconductor chip. FIG. 8A shows an example of logic circuits to read out the electrical identification code as a serial signal.

A parallel-serial transform circuit as shown in FIG. 8A is a circuit comprised of a shift resistor, for example, flip-flops. A parallel signal of 8 bits that is the electrical identification code stored in a semiconductor chip is input to the parallel-serial transform circuit (shift resistor). In the parallel-serial transform circuit (shift resistor), when a control signal and internal resistor signal for security are enabled (read permission), the flip-flops constituting the parallel-serial transform circuit (shift resistor) are driven by a clock signal, and each bit of the parallel signal is output as a serial signal.

FIG. 8B shows an example of logic circuits to read out the electrical identification code as a parallel signal. A signal of 8 bits is required to read out the electrical identification code input as a parallel signal to a selector as a parallel output signal, and as such a signal, a signal used in the chip is used without modification. Whether or not to read the electrical identification code is selected by a selector signal. Only in the case where the selector signal is of readout and the internal resistor signal for security is enabled, the electrical identification code stored in the semiconductor chip is read out as a parallel signal.

The present invention is not limited to the above described embodiments, and various variations and modifications may be possible without departing from the scope of the present invention.

This application is based on the Japanese Patent application No. 2004-360181 filed on Dec. 13, 2004, entire content of which is expressly incorporated by reference herein.

1. A semiconductor chip wherein an optically readable wiring pattern associated with an electrically readable identification code is formed as an optical identification code.

2. The semiconductor chip according to claim 1, wherein the optically readable wiring pattern is formed on a top layer of the semiconductor chip or a layer that is optically identifiable from the top layer.

3. The semiconductor chip according to claim 1, wherein the optically readable wiring pattern is part of wiring of memory elements that electrically store an identification code, and comprised of a combination of wiring forms corresponding to binary output values of the memory elements.

4. A method of manufacturing a semiconductor chip, comprising the steps of:
forming a plurality of memory elements to store an electrical identification code on a wafer;
further forming a wiring layer on the memory elements via an insulating layer;
coating the wiring layer with a resist film;
forming a wiring pattern such that an output value of each of the memory elements is 1 or 0 by electron beam lithography or laser beam lithography; and
etching the wiring layer with the wiring pattern to form an optically readable wiring pattern associated with the electrical identification code.

5. The method of manufacturing a semiconductor chip according to claim 4, wherein the wiring pattern is formed on a layer optically identifiable from a top layer.

6. A system of managing a semiconductor chip, comprising:
an optically reading apparatus that reads an optically readable wiring pattern of a memory element, the pattern associated with an electrically readable identification code;
an electrically reading apparatus that reads the electrically readable identification code; and
a management apparatus that manages a semiconductor chip using output information of the optically reading apparatus and output information of the electrically reading apparatus.

7. The system of managing a semiconductor chip according to claim 6, wherein the optically readable wiring pattern is formed on a top layer of the semiconductor chip or a layer that is optically identifiable from the top layer.

8. The system of managing a semiconductor chip according to claim 7, wherein the optically readable wiring pattern is part of wiring of memory elements that electrically store an identification code, and comprised of a combination of wiring forms corresponding to binary output values of the memory elements.
